(19) United States
(12) Patent Application Publication
(10) Pub. No.: US 2020/0243735 A1
(43) Pub. Date: Jul. 30, 2020

(54) MICROLED DISPLAY AND A METHOD OF FORMING THE SAME

(71) Applicant: Prilit Optronics, Inc., Tainan City (TW)

(72) Inventors: Hsing Ying Lee, Tainan City (TW); Biing-Seng Wu, Tainan City (TW); Shih-Wei Chuang, Tainan City (TW)

(21) Appl. No.: 16/260,778

(22) Filed: Jan. 29, 2019

(51) Int. Cl. H01L 33/60; H01L 33/00; H01L 33/30; F21V 31/00; F21V 8/00

(52) U.S. Cl. CPC H01L 33/60; H01L 33/0062; G02B 6/0073; F21V 31/005; G02B 6/0055; H01L 33/30

(57) ABSTRACT

A method of forming a micro light-emitting diode (microLED) display includes providing a substrate with a plurality of microLEDs and at least one integrated circuit disposed thereon; and forming a planarization layer to cover the microLEDs and the at least one integrated circuit. The planarization layer acts as both a light blocking layer and a corrosion-resistant layer.

### BACKGROUND OF THE INVENTION

### 1. Field of the Invention

The present invention generally relates to a micro light-emitting diode (microLED), and more particularly to a method of forming a microLED display.

### 2. Description of Related Art

A micro light-emitting diode (microLED, mLED or μLED) display panel is one of flat display panels, and is composed of microscopic microLEDs each having a size of 1-10 micrometers. Compared to conventional liquid crystal display panels, the microLED display panels offer better contrast, response time and energy efficiency. Although both organic light-emitting diodes (OLEDs) and microLEDs possess good energy efficiency, the microLEDs, based on group III/V (e.g., GaN) LED technology, offer higher brightness, higher luminous efficacy and longer lifespan than the OLEDs.

FIG. 1 shows a cross-sectional view of a conventional microLED display 100 with microLEDs 12 and an integrated circuit 13 disposed on a glass substrate 11. A first protective layer is formed over the integrated circuit 13, and a second protective layer 15 is then entirely formed to cover the microLEDs 12 and the integrated circuit 13. As the integrated circuit 13 (for example, with a height of 150 micrometers) is commonly higher than the microLED 12 (for example, with a height less than 10 micrometers), the top surface of the resultant microLED display 100 has sharp contrast, which causes uneven pressure when the microLED display 100 is flipped and the bottom surface is subjected to subsequent process. As a result, the glass substrate 11 may suffer fracture and/or the integrated circuit 13 may suffer damage.

A need has thus arisen to propose a novel method of forming a microLED display to overcome drawbacks of the conventional microLED display.

### SUMMARY OF THE INVENTION

In view of the foregoing, it is an object of the embodiment of the present invention to provide a method of forming a microLED display with simplified process and/or a flat top surface.

According to one embodiment, a micro light-emitting diode (microLED) display is formed with the following steps. A substrate with a plurality of microLEDs and at least one integrated circuit disposed thereon is provided. A planarization layer is formed to cover the microLEDs and the at least one integrated circuit. The planarization layer acts as both a light blocking layer and a corrosion-resistant layer.

### BRIEF DESCRIPTION OF THE DRAWINGS

FIG. 1 shows a cross-sectional view of a conventional microLED display with microLEDs and an integrated circuit disposed on a glass substrate; and

FIG. 2A to FIG. 4B show cross-sectional views and top views illustrating a method of forming a microLED display according to one embodiment of the present invention.

### DETAILED DESCRIPTION OF THE INVENTION

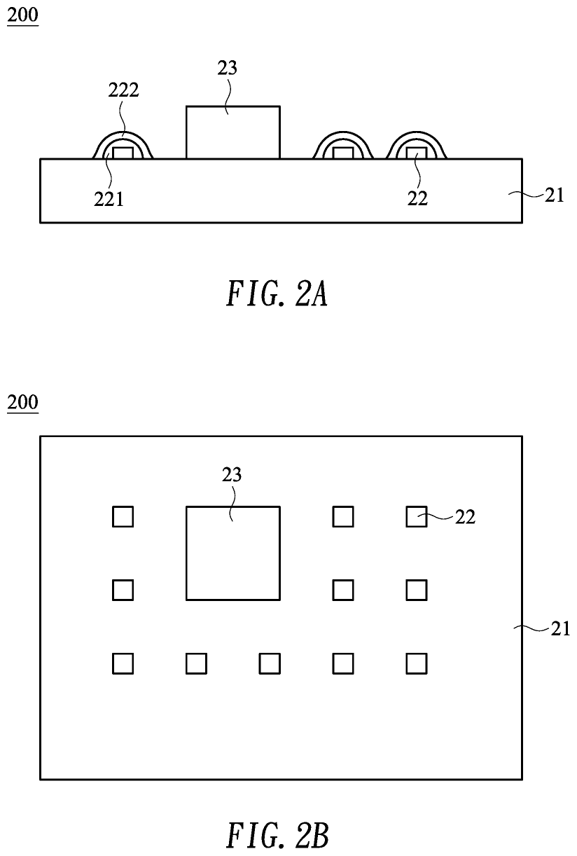

FIG. 2A to FIG. 4B show cross-sectional views and top views illustrating a method of forming a micro light-emitting diode (microLED or μLED) display 200 according to one embodiment of the present invention.

As shown in a cross-sectional view of FIG. 2A and an associated top view of FIG. 2B, a substrate 21 with microLEDs 22 and at least one integrated circuit 23 disposed thereon is provided. The substrate 21 may include glass or other materials suitable for supporting the microLEDs 22 and the integrated circuit 23. The integrated circuit 23 may, for example, be a driver that is mounted on the substrate 21 by chip-on-glass (COG) technique. It is appreciated that, although only a few microLEDs 22 are depicted, a large number of microLEDs 22 may commonly be disposed on the substrate 21. It is noted that, in the embodiment, the integrated circuit 23 has a height (e.g., 150 micrometers) being substantially larger than a height (e.g., less than 10 micrometers) of the microLED 22.

Specifically, the microLED 22 may be covered with a light guiding layer 221 that facilitate transport of the light generated by the microLED 22. The light guiding layer 221 may be covered with a reflecting layer 222 (e.g., composed of metal) that reflects light generated by the microLED 22.

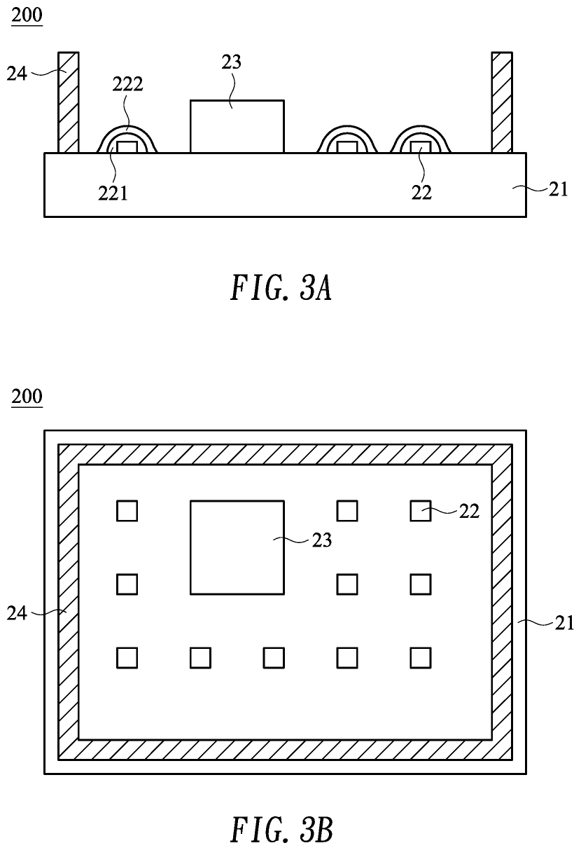

As shown in a cross-sectional view of FIG. 3A and an associated top view of FIG. 3B, a seal frame 24 (commonly called sealant) is formed on the substrate 21 and encloses at least a portion of the microLEDs 22 and the integrated circuit 23 disposed on the substrate 21. In the embodiment, the seal frame 24 having a shape of rectangle, for example, may be disposed on a periphery of the substrate 21, and may include a first adhesive material (e.g., polymers). The seal frame 24 of the embodiment may be closed or continuous without break. According to one aspect of the embodiment, the seal frame 24 has a height being larger than the height of the integrated circuit 23.

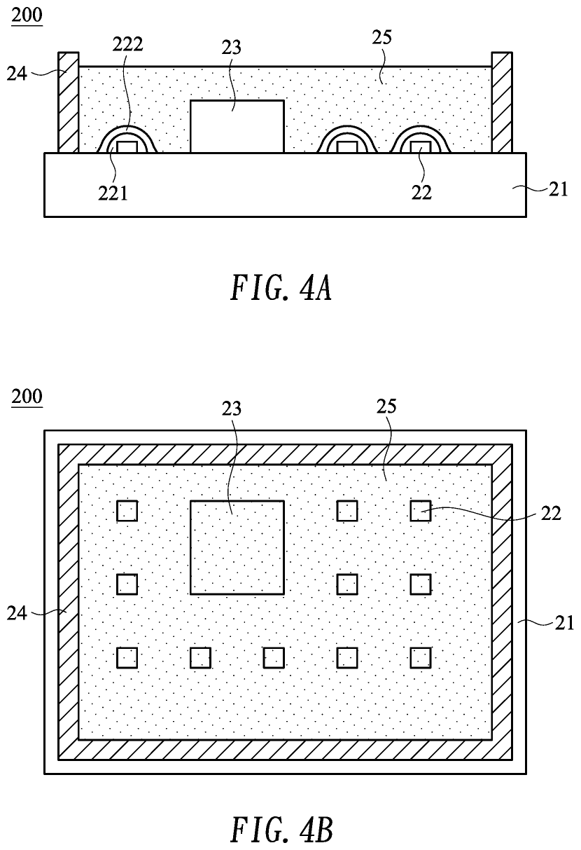

As shown in a cross-sectional view of FIG. 4A and an associated top view of FIG. 4B, an inner space defined by the seal frame 24 is filled with a second adhesive material (e.g., epoxy or silicone-based adhesive) to form a planarization layer 25 (with a substantially flat top surface) that covers the microLEDs 22 and the integrated circuit 23. That is, the planarization layer 25 has a height being larger than the height of the integrated circuit 23, but is lower than the seal frame 24. In the embodiment, the second adhesive material of the planarization layer 25 is different from the first adhesive material of the seal frame 24. Specifically, the planarization layer 25 (or the filled second adhesive material) has viscosity lower than the seal frame 24 (or the first adhesive material). According to another aspect of the embodiment, a degree of condensation (from liquid phase into solid phase) of the planarization layer 25 (or the filled second adhesive material) is low enough such that the substrate 21 (e.g., glass substrate) may not be deformed or fractured during or after curing process.

It is noted that the seal frame 24 may be omitted if the planarization layer 25 viscous enough such that the planarization layer 25 may be restricted itself (and may not flow outward) in a predetermined space that covers the microLEDs 22 and the integrated circuit 23.

According to a further aspect of the embodiment, the planarization layer 25 is dark or black in color by mixing dark or black dye to act as a light blocking layer to prevent the integrated circuit 23 from light irradiation. The planarization layer 25 also acts as a waterproof layer to prevent the integrated circuit 23 from being affected by water. In the embodiment, the planarization layer 25 (or the filled second adhesive material) may include a molding compound material (e.g., silicone).

According to a further aspect of the embodiment, the planarization layer 25 (or the filled second adhesive material) also acts as a corrosion-resistant layer to prevent the reflecting layer 222 from being corroded by water and/or oxidation. Specifically, the planarization layer 25 may include a room-temperature-vulcanizing (RTV) material such as RTV silicone.

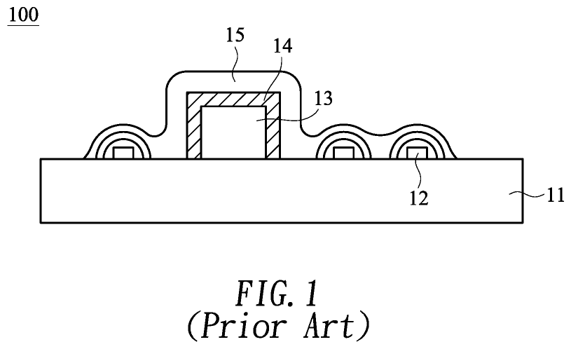

According to the embodiment as set forth above, the method of forming the microLED display 200 is simpler than the conventional method shown FIG. 1. Specifically, the microLEDs 22 and the integrated circuit 23 in the embodiment are covered with the single layer (i.e., the planarization layer 25) in one process, instead of requiring two layers (i.e., the first protective layer 14 and the second protective layer 15) formed in two processes as shown in FIG. 1. Moreover, the resultant microLED display 200 of the embodiment as shown in FIG. 4A has a substantially flat top surface instead of a top surface with sharp contrast as shown in FIG. 1. Accordingly, the substrate 21 (e.g., glass substrate) of the embodiment may not suffer fracture and/or the integrated circuit 23 may not suffer damage as in the conventional microLED display 100 (FIG. 1) due to uneven pressure caused by sharp contrast of the top surface.

Although specific embodiments have been illustrated and described, it will be appreciated by those skilled in the art that various modifications may be made without departing from the scope of the present invention, which is intended to be limited solely by the appended claims.

What is claimed is:

1. A method of forming a micro light-emitting diode (microLED) display, comprising:
providing a substrate with a plurality of microLEDs and at least one integrated circuit disposed thereon; and
forming a planarization layer to cover the microLEDs and the at least one integrated circuit;
wherein the planarization layer acts as both a light blocking layer and a corrosion-resistant layer.

2. The method of claim 1, wherein the substrate comprises glass.

3. The method of claim 1, wherein the planarization layer comprises dark or black dye.

4. The method of claim 1, wherein the planarization layer comprises room-temperature-vulcanizing (RTV) material.

5. The method of claim 1, wherein the planarization layer comprises epoxy or silicone-based adhesive.

6. The method of claim 1, wherein the planarization layer comprises molding compound material.

7. The method of claim 1, further comprising:
forming a seal frame enclosing the microLEDs and the at least one integrated circuit on the substrate before forming the planarization layer, the seal frame being higher than the planarization layer and the integrated circuit.

8. The method of claim 7, wherein the planarization layer has viscosity lower than the seal frame.

9. The method of claim 1, further comprising:
forming a light guiding layer to cover the microLEDs before forming the planarization layer; and
forming a reflecting layer on the light guiding layer.

10. The method of claim 1, wherein a degree of condensation of the planarization layer is low enough such that the substrate is not be deformed or fractured during or after curing the planarization layer.

11. A micro light-emitting diode (microLED) display, comprising:
a substrate;
a plurality of microLEDs and at least one integrated circuit disposed on the substrate; and
a planarization layer covering the microLEDs and the at least one integrated circuit;
wherein the planarization layer acts as both a light blocking layer and a corrosion-resistant layer.

12. The display of claim 11, wherein the substrate comprises glass.

13. The display of claim 11, wherein the planarization layer comprises dark or black dye.

14. The display of claim 11, wherein the planarization layer comprises room-temperature-vulcanizing (RTV) material.

15. The display of claim 11, wherein the planarization layer comprises epoxy or silicone-based adhesive.

16. The display of claim 11, wherein the planarization layer comprises molding compound material.

17. The display of claim 11, further comprising:
a seal frame formed on the substrate to enclose the microLEDs, the at least one integrated circuit and the planarization layer, the seal frame being higher than the planarization layer and the integrated circuit.

18. The display of claim 17, wherein the planarization layer has viscosity lower than the seal frame.

19. The display of claim 11, further comprising:
a light guiding layer formed on the microLEDs but below the planarization layer; and
a reflecting layer formed between the light guiding layer and the planarization layer.

20. The display of claim 11, wherein a degree of condensation of the planarization layer is low enough such that the substrate is not be deformed or fractured during or after curing the planarization layer.
